(19) United States
(12) Patent Application Publication
(10) Pub. No.: US 2021/0066482 A1
(43) Pub. Date: Mar. 4, 2021

(54) SEMICONDUCTOR DEVICE, METHOD FOR MANUFACTURING SEMICONDUCTOR DEVICE AND ELECTRONIC APPARATUS

(71) Applicant: GUANGDONG ZHINENG TECHNOLOGY CO., LTD., Guangzhou (CN)

(72) Inventor: Zilan LI, Guangzhou (CN)

(21) Appl. No.: 16/937,994

(22) Filed: Jul. 24, 2020

(30) Foreign Application Priority Data
Aug. 30, 2019 (CN) 201910822402.2

(51) Int. Cl. H01L 29/778; H01L 29/66

(52) U.S. Cl. CPC H01L 29/7784; H01L 29/66462

(57) ABSTRACT

The present disclosure provide a semiconductor device, a method for manufacturing a semiconductor device and an electronic apparatus. The device includes: a substrate; a first semiconductor layer formed on the substrate; a second semiconductor layer formed on the first semiconductor layer, the first semiconductor layer having a smaller band gap than the second semiconductor layer; a first electrode and a third electrode formed on the first or second semiconductor layer; a second electrode formed on the second semiconductor layer, and a third semiconductor layer.

### CROSS-REFERENCE TO RELATED APPLICATION

The present disclosure claims the priority to the Chinese patent application with the filing number 2019108224022 entitled “Semiconductor Device and Manufacturing Method thereof” filed on Aug. 30, 2019 with the Chinese Patent Office, the contents of which are incorporated herein by reference in its entirety.

### TECHNICAL FIELD

The present disclosure relates to the technical field of semiconductors, in particular to a semiconductor device, a method for manufacturing a semiconductor device and an electronic apparatus.

### BACKGROUND ART

Group III nitride semiconductors are important new semiconductor materials, mainly including AlN, GaN, InN and compounds of these materials such as AlGaN, InGaN, and AlInGaN. Due to the advantages of direct band gap, wide band gap, high breakdown field strength, and high saturated electron velocity, the group III nitride semiconductors have a broad application prospect in fields such as light-emitting devices, power electronics, and radio frequency devices.

### SUMMARY

A semiconductor device provided according to an embodiment of the present disclosure includes: a substrate; a first semiconductor layer formed on a first surface of the substrate; a second semiconductor layer formed on a first surface of the first semiconductor layer, wherein the first semiconductor layer has a smaller band gap than the second semiconductor layer; a first electrode and a third electrode formed on the first semiconductor layer or the second semiconductor layer, a second electrode formed on the second semiconductor layer; a third semiconductor layer, wherein a length range where the third semiconductor layer is projected onto the substrate is within a length range where the second electrode is projected onto the substrate, and the third semiconductor layer is a P-type semiconductor layer.

A method for manufacturing semiconductor device is provided according to an embodiment of the present disclosure. The method for manufacturing semiconductor device includes: providing a substrate; forming a first semiconductor layer on a first surface of the substrate; forming a third semiconductor layer in the first semiconductor layer; forming a second semiconductor layer on a first surface of the first semiconductor layer, wherein the first semiconductor layer has a smaller band gap than the second semiconductor layer, thereby forming a two-dimensional charge carrier gas at an interface between the first semiconductor layer and the second semiconductor layer; forming a first electrode and a third electrode in ohmic contact with the two-dimensional charge carrier gas, and forming a second electrode located at a first surface side of the second semiconductor layer, wherein a length range where the third semiconductor layer is projected onto the substrate is located within a length range where the second electrode is projected onto the substrate.

An electronic apparatus provided according to an embodiment of the present disclosure includes the above semiconductor device.

### BRIEF DESCRIPTION OF DRAWINGS

In order to more clearly illustrate technical solutions of embodiments of the present disclosure, accompanying drawings which need to be used for the embodiments will be introduced briefly below. It should be understood that the accompanying drawings below merely show some embodiments of the present disclosure, and therefore should not be considered as limitation on the scope. A person ordinarily skilled in the art still could obtain other relevant accompanying drawings according to these accompanying drawings, without using inventive efforts.

FIG. 1 shows a schematic cross-sectional view of a structure of a first semiconductor device provided in an embodiment;

FIG. 2 shows a schematic cross-sectional view of a modified structure of the first semiconductor device provided in an embodiment;

FIG. 3 shows a schematic cross-sectional view of a modified structure of the first semiconductor device provided in an embodiment;

FIG. 4 shows an energy band diagram of the first semiconductor device provided in an embodiment;

FIG. 5 shows a schematic cross-sectional view of a modified structure of the first semiconductor device provided in an embodiment;

FIG. 6 shows a schematic cross-sectional view of a structure of a second semiconductor device provided in an embodiment;

FIG. 7 shows a schematic cross-sectional view of a structure of a third semiconductor device provided in an embodiment;

FIG. 8 shows a schematic cross-sectional view of a structure of a fourth semiconductor device provided in an embodiment;

FIG. 9 shows a schematic top view of a structure of a fifth semiconductor device provided in an embodiment;

FIG. 10 shows a perspective view of the structure of the fifth semiconductor device provided in an embodiment;

FIG. 11 shows a schematic cross-sectional view of a structure of a sixth semiconductor device provided in an embodiment;

FIG. 12-FIG. 22 show schematic cross-sectional views of a method for manufacturing the first and second semiconductor devices provided in an embodiment;

FIG. 23 shows a schematic cross-sectional view of a method for manufacturing the third semiconductor device provided in an embodiment;

FIG. 24 shows a schematic cross-sectional view of a method for manufacturing the fourth semiconductor device provided in an embodiment; and

FIG. 25 shows a schematic cross-sectional view of a method for manufacturing the fifth semiconductor device provided in an embodiment.

Reference signs: 100-substrate; 10-opening; 101-second insulation layer; 102-first semiconductor layer; 103-second semiconductor layer; 104 (104′)-third semiconductor layer; 105-first insulation layer; 106-first electrode; 107-third electrode; 108-second electrode; 109-third insulation layer; 110-fourth electrode; 111-seed layer; 112-fifth semiconductor layer; 120-fourth semiconductor layer.

### DETAILED DESCRIPTION OF EMBODIMENTS

Exemplary contents disclosed in the present disclosure will be described below in conjunction with accompanying drawings. For the sake of clarity and conciseness, not all features of the contents actually disclosed in the present disclosure are described in the description. However, it should be appreciated that many decisions specific to the present disclosure may be made in the course of developing any such actual disclosure so as to achieve the developer's specific objectives, and these decisions may vary with differences of the present disclosure.

It also should be noted herein that, in order to avoid obscuring the contents in the present disclosure with unnecessary details, only apparatuses and structures closely related to the solutions according to the contents in the present disclosure are shown in the accompanying drawings, while other details not closely related to the contents in the present disclosure are omitted.

It should be appreciated that the contents in the present disclosure are not merely limited to the embodiments described although the following descriptions are made with reference to the accompanying drawings. Herein, features between different technical solutions may be substituted or borrowed, and one or more features may be omitted in one technical solution, where practicable. Meanwhile, the features in the embodiments of the present disclosure may be combined with each other if there is no conflict.

It should be noted that similar reference signs and letters represent similar items in the following accompanying drawings, therefore, once a certain item is defined in one accompanying drawing, it does not need to be further defined or explained in subsequent accompanying drawings.

In the description of the present disclosure, it should be noted that orientation or positional relationships indicated by terms such as “center”, “upper”, “lower”, “left”, “right”, “vertical”, “horizontal”, “inner”, and “outer”, if appear, are based on orientation or positional relationships as shown in the accompanying drawings, or orientation or positional relationships of an inventive product when being conventionally placed in use, merely for facilitating describing the present disclosure and simplifying the description, rather than indicating or suggesting that related apparatuses or elements have to be in the specific orientation or configured and operated in a specific orientation, therefore, they should not be construed as limitation on the present disclosure.

Besides, terms such as “first”, “second”, and “third”, if appear, are merely for distinctive description, but should not be construed as indicating or implying importance in the relativity.

Moreover, terms such as “horizontal”, “vertical” and “overhanging”, if appear, do not mean that a component is required to be absolutely horizontal or overhanging, but can be slightly inclined. For example, by “horizontal” it merely means that a structure is more horizontal in comparison with “vertical”, rather than being completely horizontal, while the structure can be slightly inclined.

In the description of the present disclosure, it also should be noted that unless otherwise specified and defined clearly, terms such as “provide”, “mount”, “join”, and “connect”, if appear, should be understood in a broad sense, for example, a connection can be a fixed connection, a detachable connection, or an integrated connection; it can be a mechanical connection or an electrical connection; it can be a direct connection or an indirect connection through an intermediate medium, and it also can be an inner communication between two elements. For a person ordinarily skilled in the art, specific meanings of the above-mentioned terms in the present disclosure can be understood according to specific circumstances.

Group III nitride semiconductors are important new semiconductor materials, and it is desirable to utilize the advantages of group III nitride semiconductors to develop semiconductor devices with high performances such as high withstand voltage, high power and low on-resistance through optimal designs of device structure and process. A semiconductor device made of group III nitride provided in an embodiment will be described in detail below.

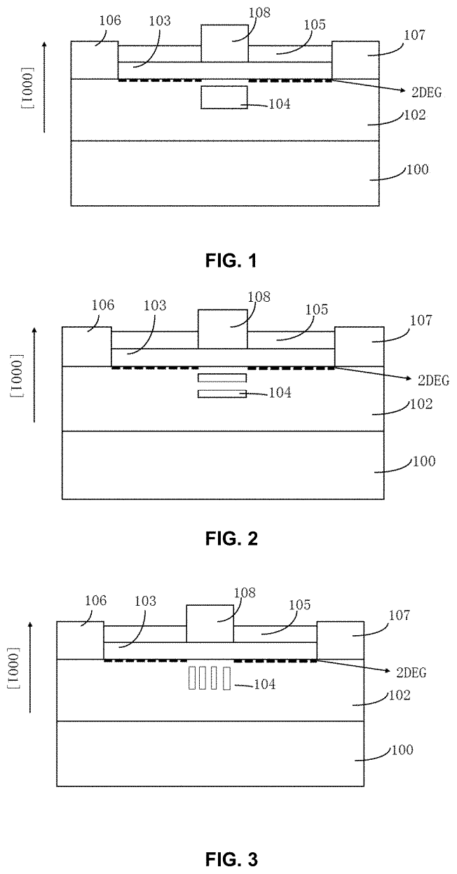

Referring to FIG. 1, FIG. 1 shows a first semiconductor device provided in the present embodiment.

Specifically, this semiconductor device is a compound semiconductor device. Optionally, this compound semiconductor device is a compound semiconductor device containing a nitride semiconductor material, also called as nitride semiconductor device. This nitride semiconductor device includes a field effect transistor using the nitride semiconductor material therein. Optionally, the field effect transistor is a GaN field effect transistor containing a GaN semiconductor material. Optionally, the GaN field effect transistor is a normally-off transistor GaN-HEMT.

As shown in FIG. 1, the semiconductor device, for example, normally-off transistor GaN-HEMT, includes a substrate 100, wherein the material of the substrate 100 may be chosen according to practical requirements, and the specific material of the substrate 100 is not limited in the present embodiment. Optionally, the substrate 100 may be sapphire, ZnO, SiC, AlN, GaAs, LiAlO, GaAlLiO, GaN, Al₂O₃ or monocrystalline silicon etc.; optionally, the substrate 100 may be of Al₂O₃ with (0001) face; optionally, the substrate 100 may be of silicon substrate 100 with (111) face.

A first semiconductor layer 102 is formed on a first surface of the substrate 100, and optionally, the first semiconductor layer 102 is a GaN layer. Optionally, the first semiconductor layer 102 is an i-GaN or unintentionally doped GaN layer. The first semiconductor layer 102 has a second surface facing the first surface of the substrate 100 and a first surface facing away from the first surface of the substrate 100. The GaN layer is parallel to the substrate 100, with an epitaxial direction being [0001] direction.

Optionally, the first semiconductor layer 102 is an intrinsic nitride semiconductor layer or an unintentionally doped nitride semiconductor layer, wherein the intrinsic nitride semiconductor layer or the unintentionally doped nitride semiconductor layer is parallel to the substrate 100, with the epitaxial direction being [0001] direction.

A second semiconductor layer 103 is formed on a first surface of the first semiconductor layer 102. The first semiconductor layer 102 has a smaller band gap width than the second semiconductor layer 103, thus forming a two-dimensional charge carrier gas, for example, 2 DEG, between the first semiconductor layer 102 and the second semiconductor layer 103. The second semiconductor layer 103 has a second surface facing the first surface of the first semiconductor layer 102 and a first surface facing away from the second surface of the first semiconductor layer 102. Optionally, the second semiconductor layer 103 is an AlN, AlGaN, InAlGaN or InAlN layer etc.

A first insulation layer 105 is formed on the first surface of the second semiconductor layer 103. The first insulation layer 105 may be a passivation layer, and optionally, the material of the passivation layer is SiO₂, SiN or Al₂O₃ etc.

A first electrode 106, a second electrode 108 and a third electrode 107 are formed, wherein the first electrode 106 and the third electrode 107 can be formed on the first semiconductor layer 102 or the second semiconductor layer 103. The second electrode 108 is formed on the second semiconductor layer 103. The first electrode 106 may be a source electrode, and forms ohmic contact with the two-dimensional charge carrier gas, the second electrode 108 may be a gate electrode, and forms Schottky contact with the second semiconductor layer 103, and the third electrode 107 is a drain electrode, and forms ohmic contact with the two-dimensional charge carrier gas. It can be clear that the first electrode 106 and the third electrode 107 also can be corresponding first doped region (source electrode region) and second doped region (drain electrode region) of this semiconductor device, for example, Si-doped regions.

Optionally, the first insulation layer 105 is formed between the second semiconductor layer 103 and the second electrode 108.

A third semiconductor layer 104 is provided below the second electrode 108. The third semiconductor layer 104 is a P-type third semiconductor layer 104, and optionally, the P-type third semiconductor layer 104 is a P-type GaN, wherein P—GaN can directly contact the second semiconductor layer 103, and it is also feasible that the two is spaced apart by a certain thickness therebetween. Illustratively, the two may be spaced apart by a certain first semiconductor material therebetween. As the third semiconductor layer 104 has a lower Fermi level, it can deplete 2 DEG located above, further causing this semiconductor device to have a higher threshold voltage and a normally-off state of the semiconductor device.

Settings of the third semiconductor layer 104, such as its thickness, length, width, and P-type doping concentration, can be provided through practical parameters, as long as 95%-100% of the 2 DEG above the third semiconductor layer can be depleted. Correspondingly, a threshold voltage of the semiconductor device is above 0 volt. Illustratively, a doping concentration of P-type impurity may be 1E+17/cm³-5E+19/cm³, and typically, the doping concentration of the P-type impurity may be 1E+18/cm³-5E+19/cm³. Doping of the P-type impurity can be determined according to concentration of the two-dimensional charge carrier gas, and the higher the concentration of the two-dimensional charge carrier gas is, the higher the doping concentration corresponding to the P-type impurity can be relatively increased. It thus can be seen that the third semiconductor layer 104 can deplete 95%-100% of the two-dimensional charge carrier gas in at least a partial region below the region of the second electrode 108, but does not deplete the two-dimensional charge carrier gas in other regions except this partial region.

A length range of orthographic projection of the third semiconductor layer 104 in a flowing direction of the two-dimensional charge carrier gas is located within a length range of orthographic projection of the second electrode 108 in this direction (i.e. ranging in a gate length), and a length range of the third semiconductor layer 104 can be set greater than 0 and less than the gate length. In other words, the length range where the third semiconductor layer 104 is projected onto the substrate 100 is located within the length range where the second electrode 108 is projected onto the substrate 100. As shown in FIG. 1, configuring the third semiconductor layer 104 within the range of gate length can avoid depletion of the two-dimensional electron gas in a non-gate stack region, further allowing the semiconductor device to have a lower on-resistance and good switching characteristics.

It should be noted that the third semiconductor layer 104 has a second surface facing the first surface of the first semiconductor layer 102 and a first surface facing away from the first surface of the first semiconductor layer 102. The third semiconductor layer 104 further has a third surface (e.g. lateral plane) connecting the first surface and the second surface of the second semiconductor layer 103. The third surface of the third semiconductor layer 104 forms an angle C with the first surface of the third semiconductor layer 104. The angle C may be within a range of 30°-90°, for example, 30°, 45°, 60°, and 90°. Optionally, the first surface of the third semiconductor layer 104 and the second surface of the third semiconductor layer 104 are parallel, that is, the third surface of the third semiconductor layer 104 forms an angle C with the second surface of the third semiconductor layer 104. The angle C may be within a range of 30°-90°, for example, 30°, 45°, 60°, and 90°.

Optionally, when a bias voltage of the second electrode 108 is 0, the two-dimensional charge carrier gas corresponding to at least a partial region of the second electrode 108 has a concentration lower than 5E+11/cm².

Optionally, a growth face of the third semiconductor layer 104 is a (112̅0) face.

Optionally, the third semiconductor layer 104 has an epitaxial direction, direction [0001], parallel to the substrate 100, and a lateral epitaxial direction of the third semiconductor layer 104 is [1120].

Optionally, the third semiconductor layer 104 may be a single-layer structure, and also may be composed of a plurality of discrete layer structures in a number of greater than or equal to 2. Illustratively, the third semiconductor layer 104 as shown in FIG. 2 may be layers that are discrete in a direction parallel to the substrate 100, and the layers that are discrete in the direction parallel to the substrate 100 may overlap in orthographic projection, and also may not overlap in orthographic projection. In FIG. 2, the number of the discrete layer structures is two. The third semiconductor layer 104 further can be, as shown in FIG. 3, composed of layers that are discrete in a direction perpendicular to the substrate 100. In FIG. 3, the number of the discrete layer structures is four. The discrete layers may be in close contact, and the discrete layers also may have a certain interval therebetween, such that performances of the semiconductor device can be improved, and the electric field in the semiconductor device can be reduced.

Optionally, the third semiconductor layer 104 may be a layer structure with a doping concentration being gradually changed. The doping concentration can be gradually varied from a center of the third semiconductor layer 104 to two sides parallel to the substrate 100 or the third semiconductor layer 104 is obtained through gradual change of a single side parallel to the substrate 100. It is also feasible that the doping concentration can be gradually varied from the center of the third semiconductor layer 104 to two sides perpendicular to the substrate 100 or that the third semiconductor layer 104 is obtained through gradual change of a single side perpendicular to the substrate 100.

Optionally, the threshold voltage of the semiconductor device can be controlled through doping elements and doping concentration of the third semiconductor layer 104, configuration of a distance between the third semiconductor layer 104 and a barrier layer, a width of the third semiconductor layer 104, material of gate electrode as well as components and thickness of the second semiconductor layer 103. Optionally, the doping concentration of the third semiconductor layer 104 is about 1E+19 cm³, the material of the gate electrode may be Au, and the third semiconductor layer 104 has a length of 0.01-10 μm, and a thickness of 0.01-10 μm. For the length (corresponding to the gate length in the device) of the third semiconductor layer 104 in the flowing direction of the two-dimensional charge carrier gas, a very thin length dimension can be further realized by precisely controlling process parameters such as epitaxy time during lateral epitaxy. As a depletion region usually has a relatively high resistance, reducing the length of this portion can effectively reduce an on resistance of the semiconductor device, and also contribute to reducing the dimension of the semiconductor device and increasing the area utilization rate of a wafer.

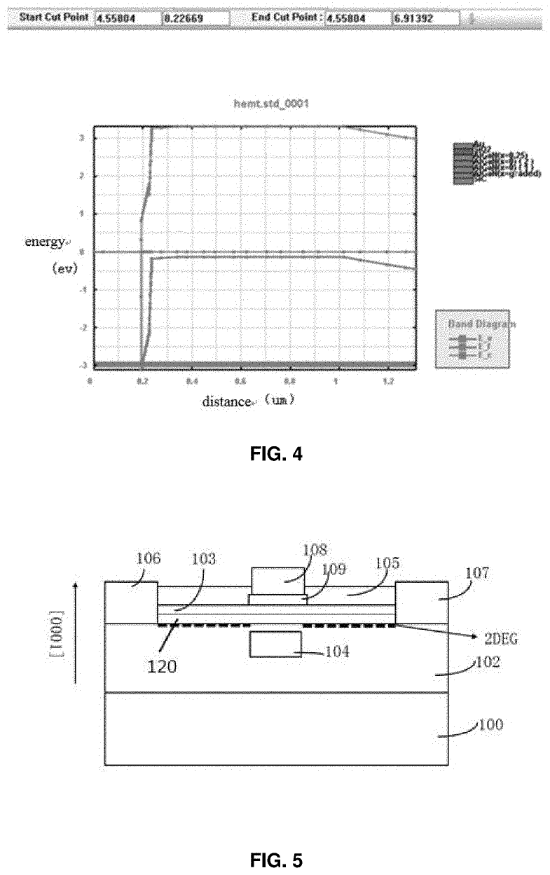

FIG. 4 is an energy band diagram of the semiconductor device. It can be seen from FIG. 4 that in the present embodiment, when the third semiconductor layer 104 is provided below the second electrode 108, a depletion layer of the semiconductor device is relatively narrow, and the two-dimensional carrier charge is depleted fast, and controllability of depletion of the two-dimensional electron gas at the region corresponding to the second electrode 108 (gate stack) in the semiconductor device can be effectively realized; and when the third semiconductor layer 104 is provided offset from the second electrode 108, the two-dimensional electron gas in regions other than the region corresponding to the second electrode 108 (gate stack) will be depleted and cannot be controlled by the second electrode 108, thereby resulting in a significant increase of the on resistance of the semiconductor device or even failure of turn-on.

As shown in FIG. 5, there further may be a fourth semiconductor layer 120 between the first semiconductor layer 102 and the second semiconductor layer 103. Optionally, the fourth semiconductor layer 120 may be an AlN layer, then the fourth semiconductor layer 120 can reduce effects such as impurity scattering, and improve mobility of electrons in a channel.

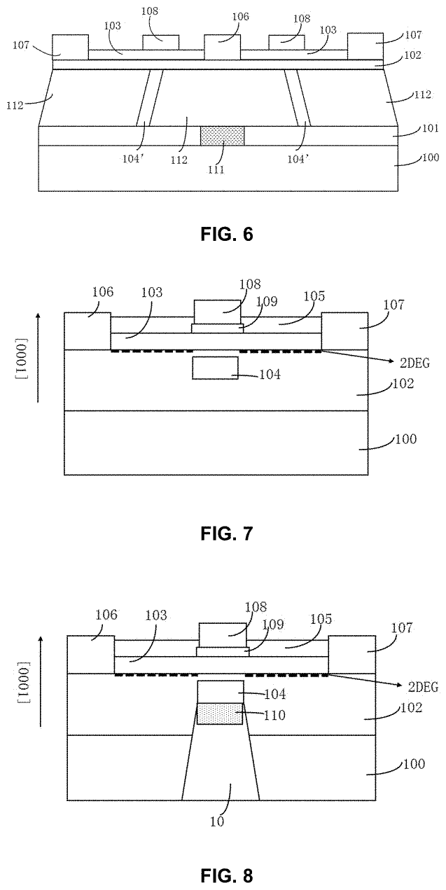

Optionally, as shown in FIG. 6, there further may be a fifth semiconductor layer 112 and/or a sixth semiconductor layer between the second semiconductor layer 103 and the substrate 100. Optionally, the fifth semiconductor layer 112 may be a group III nitride buffer layer, and the sixth semiconductor layer may be a nitride semiconductor layer, for example, an AlN layer. The fifth semiconductor layer 112 may be provided above the sixth semiconductor layer. In combination with FIG. 6, specifically, the fifth semiconductor layer 112 and/or the sixth semiconductor layer is formed between the first semiconductor layer 102 and the substrate 100.

Optionally, the third semiconductor layer 104 can be formed in the fifth semiconductor layer 112 and/or the sixth semiconductor layer, and the third semiconductor layer formed in the fifth semiconductor layer 112 and/or the sixth semiconductor layer is denoted by 104′.

In the above semiconductor device structure, the structural design of the third semiconductor layer 104, 104′ particularly avoids the case that when growing the semiconductor layer such as P—GaN after forming the first insulation layer 105 on the first surface of the second semiconductor layer 103, the P—GaN semiconductor layer has relatively poor crystal quality and electrical properties. The semiconductor device structure can obtain a high-quality P—GaN semiconductor layer in the process of manufacturing the channel or before manufacturing the channel, and further a reliable normally-off device with a relatively high threshold voltage and low gate leakage can be obtained.

Referring to FIG. 6, FIG. 6 shows a second semiconductor device provided in an embodiment.

On the basis of the first semiconductor device, a second insulation layer 101 further can be formed between the substrate 100 and the first semiconductor layer 102, a groove is formed in the second insulation layer 101 located below the first electrode 106, and a seed layer 111 is formed in the groove. It also can be understood as the seed layer 111 being located below the first electrode 106.

The seed layer 111 helps in the formation of a nitride semiconductor layer with low roughness and low dislocation density, for example, the first semiconductor layer 102 or the fifth semiconductor layer 112 can undergo symmetrical epitaxy during lateral epitaxy, improving the growth quality of the semiconductor layer and effectively utilizing a wafer area.

Referring to FIG. 7, FIG. 7 shows a third semiconductor device provided in an embodiment.

On the basis of the first semiconductor device, there further may be a third insulation layer 109 between the second semiconductor layer 103 and the second electrode 108, and the third insulation layer 109 may be silicon dioxide, silicon nitride or Al₂O₃ and so on. Configuration of the third insulation layer 109 can further reduce a gate leakage current of the second electrode 108 (gate electrode), and meanwhile, existence of the third insulation layer 109 can expand the voltage range of the gate electrode, and enhance reliability of this semiconductor device.

In combination with FIG. 8-FIG. 11, in the semiconductor device, the third semiconductor layer 104 further can be connected with a fourth electrode 110. A specific structure is as follows:

Referring to FIG. 8, FIG. 8 shows a fourth semiconductor device provided in an embodiment.

On the basis of the first semiconductor device, an opening 10 is formed at the second surface of the substrate 100, and further the fourth electrode 110 connected with the third semiconductor layer 104 (for example, P—GaN) is formed in the opening 10. As the third semiconductor layer 104 has a floating potential when it is not connected with any electrode or potential, the threshold voltage of this semiconductor device will be unstable. But after the third semiconductor layer 104 is connected with the fourth electrode 110, the potential of the third semiconductor layer 104 can be controlled by the fourth electrode 110, such that the semiconductor device can provide a stable threshold voltage.

It can be clear that the structures of the second or third semiconductor devices can be combined on the basis of the fourth semiconductor device so as to obtain corresponding beneficial effects.

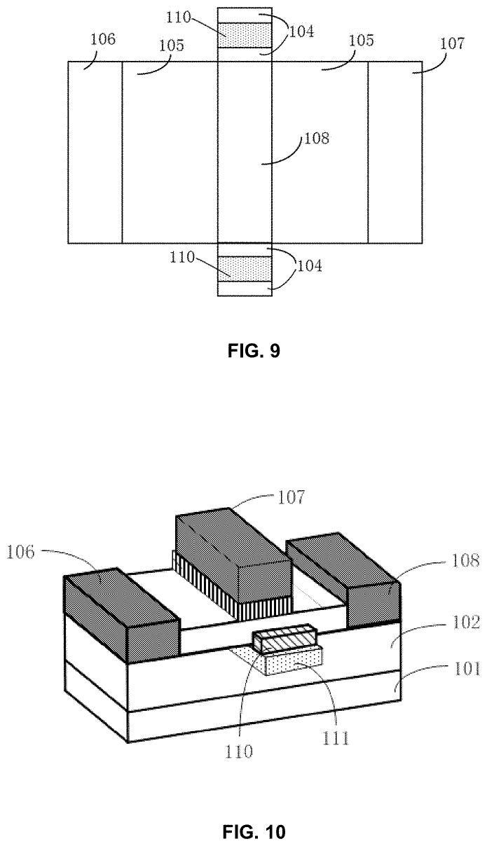

Referring to FIGS. 9-10, FIG. 9 and FIG. 10 show a fifth semiconductor device provided in an embodiment.

On the basis of the first semiconductor device, the third semiconductor layer 104 (for example, P—GaN) further can extend in a direction perpendicular to the flowing direction of the two-dimensional charge carrier gas, and the fourth electrode 110 connected with the third semiconductor layer 104 is formed at a position not covered by the orthographic projection of the second electrode 108. As the third semiconductor layer 104 has a floating potential when it is not connected with any electrode or potential, the threshold voltage of this semiconductor device will be unstable. But after the third semiconductor layer 104 is connected with the fourth electrode 110, the potential of the third semiconductor layer 104 can be controlled by the fourth electrode 110, such that the semiconductor device can provide a stable threshold voltage.

It can be clear that the structures of the second or third semiconductor devices can be combined on the basis of the fifth semiconductor device so as to obtain corresponding beneficial effects.

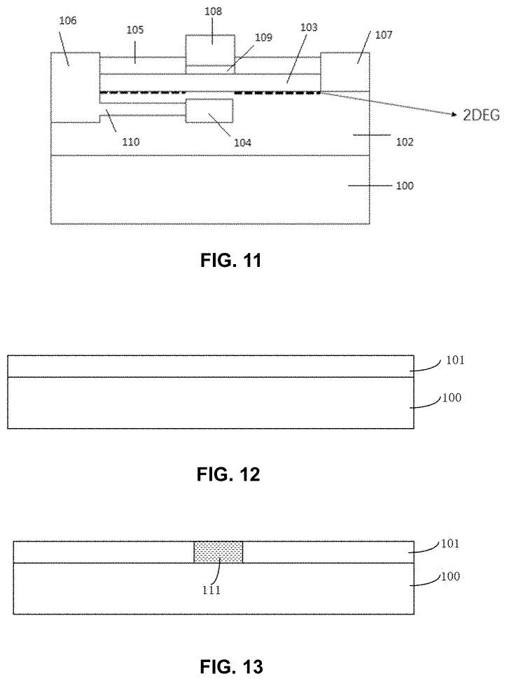

Referring to FIG. 11, FIG. 11 shows a sixth semiconductor device provided in an embodiment.

On the basis of the first semiconductor device, the fourth electrode 110 connected with the third semiconductor layer 104 (for example, P—GaN) further can be formed at the first electrode 106 of the device. Optionally, a surface of the first electrode 106, in contact with the second semiconductor layer 103, can extend downwards to form L-shape ohmic contact, so as to be connected with the third semiconductor layer 104. As the third semiconductor layer 104 has a floating potential when it is not connected with any electrode or potential, the threshold voltage of this semiconductor device will be unstable. But after the third semiconductor layer 104 is connected with the fourth electrode 110, the potential of the third semiconductor layer 104 can be controlled by the fourth electrode 110, such that the semiconductor device can provide a stable threshold voltage.

It can be clear that the structures of the second or third semiconductor devices can be combined on the basis of the sixth semiconductor device so as to obtain corresponding beneficial effects.

Similarly, the substrate 100 has a second surface opposite to the first surface, and the fourth electrode 110 connected with the third semiconductor layer 104 also can be formed at the second surface of the substrate 100.

Optionally, the fourth electrode 110 is an independent electrode, or the fourth electrode 110 is a non-independent electrode.

It can be seen that the above semiconductor device is capable of reducing the gate leakage current, has a high threshold voltage, high power, and high reliability, can achieve a low on-resistance and a normally-off state of the device, and can provide a stable threshold voltage, such that the semiconductor device has good switching characteristics.

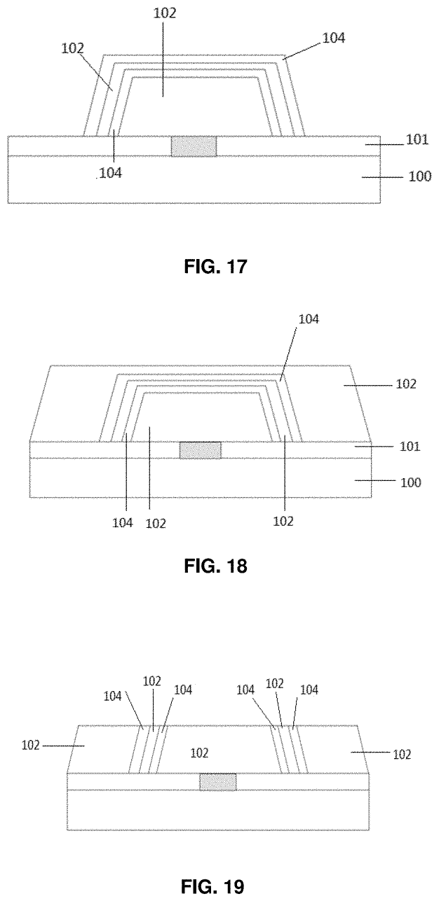

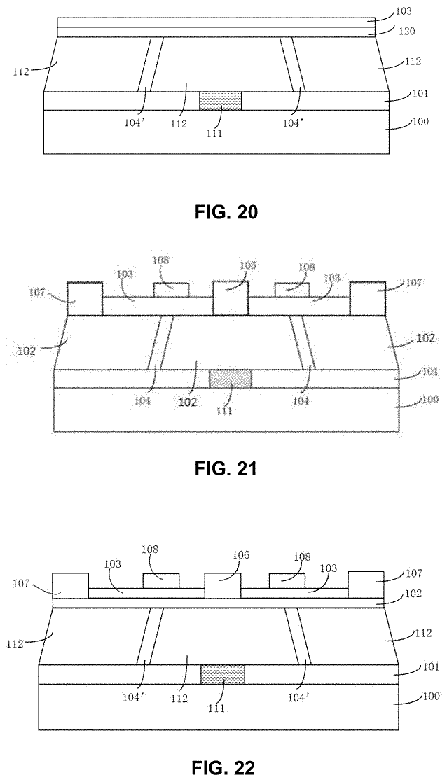

Now referring to FIGS. 12-22, FIG. 12-FIG. 22 show a method for manufacturing the first and second semiconductor devices.

Step S100: providing a substrate 100, wherein reference can be made to the above description for the selection of the material of the substrate 100, and unnecessary details will not be given herein.

Step S200: forming a first semiconductor layer 102 on a first surface of the substrate 100;

Step S300: forming a third semiconductor layer 104 in the first semiconductor layer 102;

Step S400: forming a second semiconductor layer 103 on a first surface of the first semiconductor layer 102;

wherein the first semiconductor layer 102 has a smaller band gap width than the second semiconductor layer 103, thus forming a two-dimensional charge carrier gas at an interface between the first semiconductor layer 102 and the second semiconductor layer 103;

Step S500: forming a first electrode 106 and a third electrode 107 in ohmic contact with the two-dimensional charge carrier gas, and forming a second electrode 108 located at a first surface side of the second semiconductor layer 103.

In the above, a length range where the third semiconductor layer 104 is projected onto the substrate 100 is located within a length range where the second electrode 108 is projected onto the substrate 100.

Optionally, the third semiconductor layer 104 is a P-type doped nitride layer, and a lateral growth direction of the third semiconductor layer 104 is [1120] crystal orientation.

In the above method for manufacturing the semiconductor device, prior to step S200, step S110 is further included: depositing a second insulation layer 101 on the first surface of the substrate 100, wherein the second insulation layer 101 covers the whole surface of the substrate 100. At least a part of the second insulation layer 101 is removed. Optionally, at least a part of the second insulation layer 101, corresponding to a region where the first electrode 106 (source electrode) is formed subsequently, is removed, to form an opening so as to expose a part of the substrate 100, then a seed layer 111 is formed by coplanar deposition on the second insulation layer 101 through a deposition process. The seed layer 111 and the second insulation layer 101 each have a second surface facing the first surface of the substrate 100, and a first surface facing away from the first surface of the substrate 100. In the above, the material of the second insulation layer 101 is not limited. A material that can act as a growth core of the first semiconductor layer 102 can be chosen as the material of the seed layer 111.

Alternatively, in step S110 of depositing a seed material on the first surface of the substrate 100, a part of the seed material is removed by photolithography etching, such that the remaining seed layer 111 is allowed to act as the grown core of the first semiconductor layer 102. Optionally, the region of the remaining seed layer 111 is corresponding to the region where the first electrode 106 (source electrode) region is formed subsequently. Then, an insulation material is deposited on the first surface of the substrate 100, to completely cover the substrate 100 and the seed layer 111, and a part of the insulation material is removed to form the second insulation layer 101 until the seed layer 111 is exposed. The seed layer 111 and the second insulation layer 101 each have a second surface facing the first surface of the substrate 100, and a first surface facing away from the first surface of the substrate 100.

Optionally, in step S110 of depositing a seed material on the whole first surface of the substrate 100, a part of the seed material is removed, then the second insulation layer 101 is coplanarly deposited, and at least a part of the second insulation layer 101 is removed until a part of the seed layer 111 is exposed, and the exposed part of the seed layer 111 acts as the grown core of the first semiconductor layer 102.

Optionally, in the above, removing at least a part of the second insulation layer 101 is to remove at least a part of the second insulation layer 101 corresponding to the region of the subsequent first electrode 106; or a position where a part of the seed layer 111 is exposed is corresponding to the region of the first electrode 106.

The above method for manufacturing semiconductor device further includes step S120 of forming the first semiconductor layer 102 through lateral epitaxy, with the seed layer 111 as a central selective area (core selective area), on the first surface of the second insulation layer 101 and the seed layer 111. It can be understood that the third semiconductor layer 104 also can be formed by the same method.

It can be understood that in the method for manufacturing the first semiconductor device, the above step S110, step S111 and step S120 are not indispensable. The first semiconductor layer 102 (for example, GaN) can be directly formed after step S100. A growth method of the first semiconductor layer 102 is not specially limited, while metalorganic chemical vapor deposition (MOCVD), hydride vapor phase epitaxy (HVPE) or other techniques can be used.

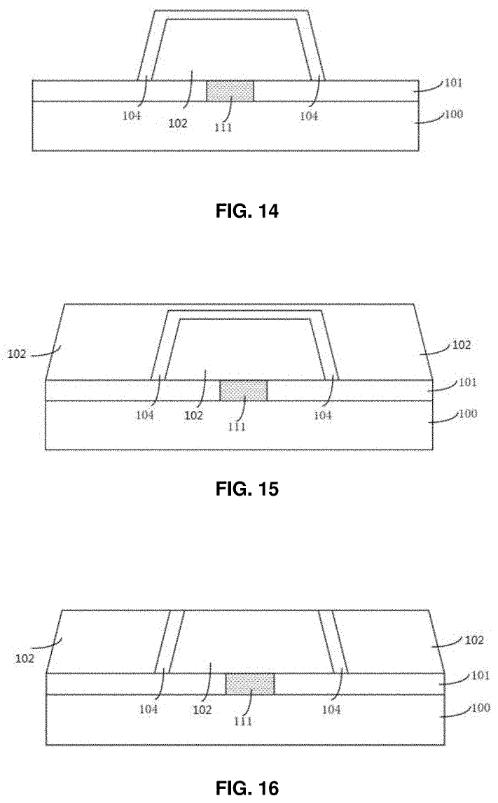

A method of forming the first semiconductor layer 102 through lateral epitaxy with the seed layer 111 as a center is specifically illustrated as follows with reference to FIGS. 14-19:

Step S121: growing, through lateral epitaxy, a first region of the first semiconductor layer 102 containing a low-doped or unintentionally doped nitride semiconductor, with the seed layer 111 as a central selective area (core), wherein the first region of the first semiconductor layer 102 starts to grow from a position where the seed layer 111 is located, and by controlling a growth rate of this first region, the growth of the first region is stopped before the first semiconductor layer 102 completely covers the second insulation layer 101.

Step S122, continuing to grow the P-type doped nitride layer on a surface and a side face of the first region of the first semiconductor layer 102, with the first region of the first semiconductor layer 102 which is grown as a core, after the P-type doped nitride layer of a certain thickness is grown, continuing to grow the semiconductor layer containing low-doped or unintentionally doped nitride, and then exposing the P-type nitride semiconductor layer and the first region of the first semiconductor layer 102 by removing a part of the low-doped or unintentionally doped nitride semiconductor layer and the P-type nitride semiconductor layer, wherein the steps of growing the P-type doped nitride layer and continuing to grow the low-doped or unintentionally doped nitride semiconductor layer can be repeated multiple times. Specifically, a part of an upper surface of the P-type nitride semiconductor layer can be removed or a part of an upper surface of the P-type nitride semiconductor layer and a part of the first region of the first semiconductor layer 102 can be removed so as to expose the P-type nitride semiconductor layer and the first region of the first semiconductor layer 102. Optionally, a length range of projection of the P-type nitride semiconductor layer is within a length range of a projection region of the second electrode 108 to be formed subsequently, and the width of the P-type nitride semiconductor layer can be greater than the width of the second electrode 108. Thus the manufacture of the third semiconductor layer 104 is completed, and more specifically, the third semiconductor layer 104 can be a P-type doped nitride layer, for example, P—GaN, of which a lateral growth direction is [112̅0] crystal direction, and a growth face may be a vertical (112̅0) face. Optionally, the third semiconductor layer 104 may specifically have a length of about 0.01-10 μm, and a height of about 0.01-10 μm. Compared with the case where P—GaN has a lateral growth direction of [101̅0] crystal direction and a stable growth face thereof is an inclined (11̅01) face, when the lateral growth direction is [112̅0] crystal direction, it has a relatively fast lateral growth rate, and performances of the semiconductor device are more excellent.

Step S123, continuing to grow a second region of the first semiconductor layer 102 containing low-doped or unintentionally doped nitride semiconductor, with the third semiconductor layer 104 and the first region of the first semiconductor layer 102 as a nucleation center, until the second region of the first semiconductor layer 102 completely covers the substrate 100 and the first insulation layer 105. A part of the low-doped or unintentionally doped nitride semiconductor layer and the P-type nitride semiconductor layer can be removed, so as to expose the P-type nitride semiconductor layer and the first region of the first semiconductor layer 102, and allow surfaces of the two to be flush, as shown in FIG. 16. Alternatively, the first surface of the first semiconductor layer 102 away from the substrate 100 is higher than the first surface of the third semiconductor layer 104 away from the substrate 100.

It can be understood that step S121-step S123 can be repeated several times, so as to prepare the third semiconductor layers 104 that are discrete as shown in FIG. 19.

It can be clear that in the process of growing the P-type doped nitride layer in step S122, the third semiconductor layer 104 in the first semiconductor device, with single-side or two-side gradually changed doping, can be manufactured by controlling the P-type doping concentration in the process. The specific form of P-type doping is not specifically limited herein.

Alternatively, the third semiconductor layer 104 also can be formed by means of ion implantation in the first semiconductor layer 102, so as to form the third semiconductor layer 104, which is discrete or gradually changed, in the first or second semiconductor device as described in the above. It can be understood that a method of forming the third semiconductor layer 104 may be a lateral epitaxy method, and also may be an ion implantation method, in this way, the third semiconductor layer 104 is prepared as a structure that is discrete or has a gradually changed doping concentration.

Step S130, depositing the second semiconductor layer 103 on the first semiconductor layer 102. It can be clear that before forming the second semiconductor layer 103, the fourth semiconductor layer 120 further can be deposited on the first semiconductor layer 102. Thus, the two-dimensional charge carrier gas is formed at an interface between the second semiconductor layer 103 and the fourth semiconductor layer 120, or between the first semiconductor layer 102 and the second semiconductor layer 103. The second semiconductor layer 103 can be in direct contact with the fourth semiconductor layer 120, or the second semiconductor layer 103 is in direct contact with the first semiconductor layer 102.

It can be clear that the fourth semiconductor layer 120 can be a nitride channel layer, and the second semiconductor layer 103 can be a nitride barrier layer; alternatively, the second semiconductor layer 103 can be a nitride barrier layer, and the first semiconductor layer 102 can be a nitride channel layer.

Step S140, forming a first electrode 106 (source electrode) and a third electrode 107 (drain electrode) in ohmic contact with the two-dimensional charge carrier gas, and a second electrode 108 (gate electrode) located above a first surface of the third semiconductor layer 104. Positions of the first electrode 106 and the third electrode 107 are not limited, and they can be directly formed on the second semiconductor layer 103, and also can be directly provided into the channel layer. An exemplary structure is as shown in FIG. 21.

It can be understood that in step S120, on the first surface of the second insulation layer 101 and the seed layer 111, the fifth semiconductor layer 112 further can be formed through lateral epitaxy with the seed layer 111 as a center, as shown in FIG. 22. Subsequently, a method of forming the fifth semiconductor layer 112 and the third semiconductor layer 104′ through lateral epitaxy/with the seed layer 111 as a central selective area is the same as the preceding method of forming the first semiconductor layer 102 and the third semiconductor layer 104, and unnecessary details will not be given herein. Then other structures such as the first semiconductor layer 102 and the second semiconductor layer 103 can be successively formed by known methods. An exemplary structure of the fifth semiconductor layer 112 is as shown in FIG. 22.

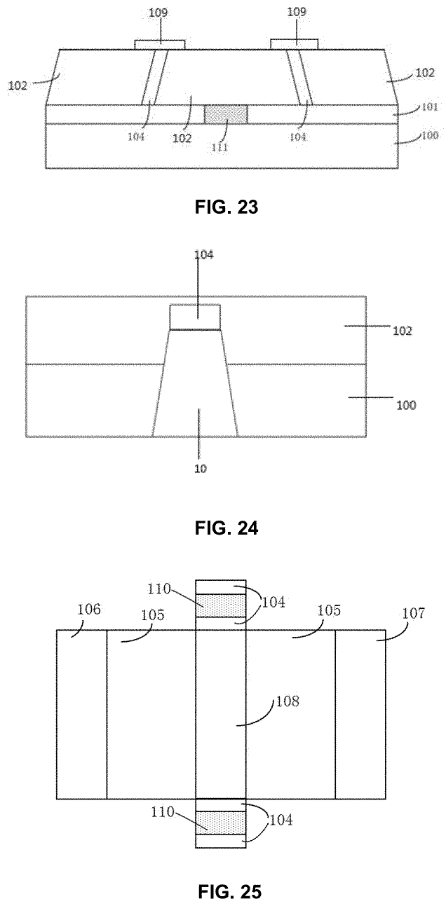

Now referring to FIG. 23, FIG. 23 shows a method for manufacturing the third semiconductor device.

In the above, between step S130 and step S140 of the method for manufacturing the first and second semiconductor devices, the first insulation layer 105 can be formed by completely depositing an insulation material on the first surface of the second semiconductor layer 103, or the third insulation layer 109 is formed at a position corresponding to the second electrode 108 through relevant processes such as etching process. The insulation material may be silicon dioxide, silicon nitride or Al₂O₃ etc. The second semiconductor layer 103 may have the first insulating layer 105 and the third insulating layer 109 simultaneously or alternatively.

Now referring to FIG. 24, FIG. 24 shows a method for manufacturing a fourth semiconductor device.

In the above, there further may be step S150 in the method for manufacturing the first and second semiconductor devices. In step S150, an etching process is carried out at the second surface of the substrate 100 corresponding to the position where the third semiconductor layer 104 is formed, to form the opening 10. The opening 10 directly reaches to the third semiconductor layer 104. Then the fourth electrode 110 is formed on the third semiconductor layer 104 through a process such as deposition, such that the potential of the third semiconductor layer 104 can be controlled, allowing a stable threshold voltage of the semiconductor device.

Now referring to FIG. 25, FIG. 25 shows a method for manufacturing a fifth semiconductor device.

In the above, there further may be step S150 in the method for manufacturing the first and second semiconductor devices. In step S150, the third semiconductor layer 104 extends and grows in a direction perpendicular to the flowing direction of the two-dimensional carrier charge, the opening 10 is formed through etching at a position of the first surface or the second surface of the third semiconductor layer 104 uncovered by the orthographic projection of the second electrode 108, and the fourth electrode 110 connected with the third semiconductor layer 104 is formed in the opening 10 through a process such as sputtering, such that the potential can be controlled, and the threshold voltage of the device is stable.

An embodiment further provides an electronic apparatus, which includes the above semiconductor device, and has all advantages of the semiconductor device. This electronic apparatus may be a supply unit, a server, a charger, a cellphone or an amplifier.

An embodiment further provides a supply unit, including the above semiconductor device. The supply unit includes a primary circuit, a secondary circuit, a transformer and so on, wherein both the primary circuit and the secondary circuit include a switching element, wherein the switching element is any one of the multiple semiconductor devices described above.

An embodiment further provides a cellphone, including the above semiconductor device. The cellphone includes a display screen, a charger and so on, wherein the charger includes any one of the multiple semiconductor devices described above.

An embodiment further provides an amplifier. The amplifier may be a power amplifier in the field such as mobile phone base station, and the power amplifier may include any one of the multiple semiconductor devices described above.

The present disclosure is described in the above in connection with the specific embodiments, but a person skilled in the art should understand that all of these descriptions are illustrative, rather than limitation on the scope of protection of the present disclosure. A person skilled in the art could make various variations and modifications to the present disclosure in accordance with the spirit and principles of the present disclosure, and these variations and modifications are also within the scope of the present disclosure.

### INDUSTRIAL APPLICABILITY

In summary, the present disclosure provides a semiconductor device, a method for manufacturing semiconductor device and an electronic apparatus. The above semiconductor device is simple in structure, has a high threshold voltage, can achieve a normally-off state of the device, and meanwhile has a low on-resistance and good switching characteristics.

1. A semiconductor device, comprising:
a substrate;
a first semiconductor layer, provided on a first surface of the substrate;
a second semiconductor layer, provided on a first surface of the first semiconductor layer,
wherein the first semiconductor layer has a smaller band gap than the second semiconductor layer;
a first electrode and a third electrode are provided on the first semiconductor layer or the second semiconductor layer, a second electrode is provided on the second semiconductor layer; and
a third semiconductor layer, wherein a length range where the third semiconductor layer is projected onto the substrate is within a length range where the second electrode is projected onto the substrate, and the third semiconductor layer is a P-type semiconductor layer.

2. The semiconductor device according to claim 1, wherein a two-dimensional charge carrier gas is formed between the first semiconductor layer and the second semiconductor layer, and the third semiconductor layer depletes 95%-100% of the two-dimensional charge carrier gas in at least a partial region below a region of the second electrode, but does not deplete the two-dimensional charge carrier gas in other regions except the partial region.

3. The semiconductor device according to claim 1, wherein a two-dimensional charge carrier gas is formed between the first semiconductor layer and the second semiconductor layer, wherein when a bias voltage of the second electrode is 0, the two-dimensional charge carrier gas corresponding to at least a partial region of the second electrode has a concentration lower than 5E+11/cm².

4. The semiconductor device according to claim 1, wherein the third semiconductor layer has an epitaxial direction, direction [0001], parallel to the substrate, and a lateral epitaxial direction of the third semiconductor layer is [112̅0].

5. The semiconductor device according to claim 1, wherein the third semiconductor layer is a single-layer structure, or comprises a plurality of discrete layer structures in a number of greater than or equal to 2.

6. The semiconductor device according to claim 5, wherein the discrete layer structures are in close contact, or the discrete layer structures have an interval therebetween.

7. The semiconductor device according to claim 1, wherein the third semiconductor layer is a layer structure with a gradually changed doping concentration.

8. The semiconductor device according to claim 1, wherein a fourth semiconductor layer is further formed between the first semiconductor layer and the second semiconductor layer.

9. The semiconductor device according to claim 1, wherein a first insulation layer is formed on a first surface of the second semiconductor layer; and/or
a second insulation layer is formed between the substrate and the first semiconductor layer; and/or
a third insulation layer is further formed between the second semiconductor layer and the second electrode.

10. The semiconductor device according to claim 1, wherein a seed layer is formed in a second insulation layer located between the substrate and the first semiconductor layer, and the seed layer is located below the first electrode.

11. The semiconductor device according to claim 1, wherein the third semiconductor layer is connected with a fourth electrode.

12. The semiconductor device according to claim 11, wherein an opening is provided at a second surface of the substrate, and the fourth electrode connected with the third semiconductor layer is provided in the opening, or
the third semiconductor layer extends in a direction perpendicular to a flowing direction of the two-dimensional charge carrier gas, and the fourth electrode connected with the third semiconductor layer is provided at a position uncovered by orthographic projection of the second electrode, or
the fourth electrode connected with the third semiconductor layer is provided at the first electrode, or
the substrate has a second surface opposite to the first surface, and the fourth electrode connected with the third semiconductor layer is provided at the second surface of the substrate.

13. The semiconductor device according to claim 11, wherein the fourth electrode is an independent electrode, or the fourth electrode is a non-independent electrode.

14. A method for manufacturing a semiconductor device, comprising:
step S100: providing a substrate;
step S200: forming a first semiconductor layer on a first surface of the substrate;
step S300: forming a third semiconductor layer in the first semiconductor layer; and
step S400: forming a second semiconductor layer on a first surface of the first semiconductor layer,
wherein the first semiconductor layer has a smaller band gap than the second semiconductor layer, thus forming a two-dimensional charge carrier gas at an interface between the first semiconductor layer and the second semiconductor layer; and
step S500: providing a first electrode and a third electrode in ohmic contact with the two-dimensional charge carrier gas, and providing a second electrode located at a first surface side of the second semiconductor layer,
wherein a length range where the third semiconductor layer is projected onto the substrate is located within a length range where the second electrode is projected onto the substrate.

15. The method for manufacturing a semiconductor device according to claim 14, wherein prior to the step S200, the method for manufacturing a semiconductor device further comprises step S110: forming a second insulation layer by depositing on the first surface of the substrate, wherein the second insulation layer covers a whole surface of the substrate, removing at least a part of the second insulation layer to form an opening, so as to expose a part of the substrate, and forming a seed layer by coplanarly depositing on the second insulation layer through a deposition process, wherein the seed layer acts as a growth core of the first semiconductor layer.

16. The method for manufacturing a semiconductor device according to claim 15, wherein the method for manufacturing a semiconductor device further comprises step S121: growing, through lateral epitaxy, a first region of the first semiconductor layer containing a low-doped or unintentionally doped nitride semiconductor, with the seed layer as a core, wherein the first region of the first semiconductor layer starts to grow from a position where the seed layer is located, and the growth of the first region is stopped by controlling a growth rate of the first region, before the first semiconductor layer completely covers the second insulation layer.

17. The method for manufacturing a semiconductor device according to claim 16, wherein the method for manufacturing a semiconductor device further comprises step S122 of:
growing a P-type doped nitride layer on a surface and a side face of the first region of the first semiconductor layer, wherein the first region of the first semiconductor layer which is grown is used as a core;
continuing, after the P-type doped nitride layer of a certain thickness is grown, to grow a semiconductor layer containing low-doped or unintentionally doped nitride; and
exposing a P-type nitride semiconductor layer and the first region of the first semiconductor layer by removing a part of a low-doped or unintentionally doped nitride semiconductor layer and the P-type nitride semiconductor layer,
wherein steps of growing the P-type doped nitride layer and continuing to grow the low-doped or unintentionally doped nitride semiconductor layer can be repeated multiple times.

18. The method for manufacturing a semiconductor device according to claim 14, wherein the third semiconductor layer is the P-type doped nitride layer, and a lateral growth direction of the third semiconductor layer is [112̅0] crystal direction.

19. The method for manufacturing a semiconductor device according to claim 14, wherein the method for manufacturing a semiconductor device further comprises step S150 of:
carrying out an etching process at a second surface of the substrate corresponding to a position where the third semiconductor layer is formed, to provide an opening, wherein the opening directly reaches to the third semiconductor layer, and then providing a fourth electrode on the third semiconductor layer through a deposition process; or
making the third semiconductor layer to extend and grow in a direction perpendicular to a flowing direction of a two-dimensional carrier charge, providing an opening through etching at a position of a first surface or a second surface of the third semiconductor layer uncovered by orthographic projection of the second electrode, and providing a fourth electrode connected with the third semiconductor layer in the opening through a sputtering process.

20. An electronic apparatus, comprising the semiconductor device according to claim 1.
